(19) United States
(12) Patent Application Publication
(10) Pub. No.: US 2009/0267057 A1
(43) Pub. Date: Oct. 29, 2009

(54) ORGANIC FIELD-EFFECT TRANSISTOR FOR SENSING APPLICATIONS

(75) Inventors: Sepas Setayesh, Eindhoven (NL); Dagobert Michel De Leeuw, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/302,045

(22) PCT Filed: May 10, 2007
(86) PCT No.: PCT/IB07/51764

§ 371 Date: Nov. 24, 2008

(30) Foreign Application Priority Data
May 29, 2006 (EP) 06114645.2

(51) Int. Cl. H01L 51/30; H01L 29/786; H01L 51/10

(52) U.S. Cl. 257/40; 257/347; 257/253; 257/E51.027; 257/E51.006; 257/E29.273

(57) ABSTRACT

Field-effect transistor comprising a gate electrode layer, a first dielectric layer, a source electrode, a drain electrode, an organic semiconductor and a second dielectric layer, wherein the first dielectric layer is located on the gate electrode layer, the source electrode, the drain electrode and the organic semiconductor are located above the first dielectric layer, the source electrode and the drain electrode are in contact with the organic semiconductor, wherein the second dielectric layer is placed upon the assembly of source electrode, drain electrode and organic semiconductor and wherein during operation of the field-effect transistor the capacitance of the assembly comprising the gate electrode layer and the first dielectric layer is lower than the capacitance of the second dielectric layer. Further a sensor system comprising such a field-effect transistor and the use of a sensor system for detecting molecules is disclosed.

### BACKGROUND OF THE INVENTION

The present invention concerns a field-effect transistor. More specifically, the present invention concerns a field-effect transistor comprising a gate electrode layer, a first dielectric layer, a source electrode, a drain electrode, an organic semiconductor and a second dielectric layer, wherein the first dielectric layer is located on the gate electrode layer, the source electrode, the drain electrode and the organic semiconductor are located above the first dielectric layer, the source electrode and the drain electrode are in contact with the organic semiconductor and wherein the second dielectric layer is placed upon the assembly of source electrode, drain electrode and organic semiconductor. Furthermore, the present invention concerns a sensor system comprising at least one field-effect transistor according to the present invention and the use of a sensor system according to the present invention for detecting molecules.

The ion sensitivity of silicon-based field-effect transistors (FETs) has been already the subject of research for a long time. However, ion sensitive field-effect transistors (ISFETs) have the disadvantage of using a reference chemical electrode. That implies a large size and the use of an electrolyte.

Field-effect transistors based on different conjugated oligomers and polymers have been known for more than a decade. They represent an alternative to the costly silicon-based transistors for different applications.

EP 1 348 951 A1 discloses a molecularly controlled dual gated field-effect transistor for sensing applications. It mentions a sensing device comprising a sensing layer having at least one functional group that binds to the semiconducting channel layer and at least another functional group that serves as a sensor, a semiconducting channel layer having a first surface and a second surface which is opposite to said first surface, a drain electrode, a source electrode and a gate electrode, wherein said source electrode, said drain electrode and said gate electrode are placed on the first surface of said semiconducting channel layer and that said sensing layer is on the surface of said semiconducting channel layer, said sensing layer being in contact with the semiconducting channel layer and said semiconducting channel layer has a thickness below 5000 nm.

This assembly however is disadvantageous because it does not guarantee a complete overlap between the gate electrode and the semiconducting channel layer. This in turn leads to a greater contact resistance and a lower performance of the field-effect transistor, especially in the case when organic semiconductors are concerned.

US 2004/0195563 discloses an organic field-effect transistor for the detection of biological target molecules and a method of fabricating the transistor. The transistor comprises a transistor channel having a semiconductive film comprising organic molecules. Probe molecules capable of binding to target molecules are coupled to an outer surface of the semiconductive film in such a way that the interior of the film remains substantially free of the probe molecules.

Due to the channel structure, this transistor is difficult and/or expensive to manufacture. For example, photo resist technology must be employed. Additionally, keeping the interior of the film substantially free of the probe molecules or the surrounding electrolyte solution is no easy task given the flow characteristics of the medium, the diffusion of the electrolyte and the difficulty of arranging a molecularly tight layer of probe molecules. Once the interior of the film comes into contact with probe molecules or electrolyte solution, a short circuit may occur between source and drain electrode.

There still exists a need in the art for highly selective field-effect transistors capable of performing sensing operations during adverse conditions such as biological environments like in vivo or in vitro conditions.

### SUMMARY OF THE INVENTION

The present invention has the object of overcoming at least one of the drawbacks in the art. More specifically, it has the object of providing a field-effect transistor with enhanced sensitivity that is capable of performing under adverse conditions.

The object is reached by providing a field-effect transistor comprising a gate electrode layer, a first dielectric layer, a source electrode, a drain electrode, an organic semiconductor and a second dielectric layer, wherein the first dielectric layer is located on the gate electrode layer, the source electrode, the drain electrode and the organic semiconductor are located above the first dielectric layer, the source electrode and the drain electrode are in contact with the organic semiconductor, wherein the second dielectric layer is placed upon the assembly of source electrode, drain electrode and organic semiconductor and wherein during operation of the field-effect transistor the capacitance of the assembly comprising the gate electrode layer and the first dielectric layer is lower than the capacitance of the second dielectric layer.

### BRIEF DESCRIPTION OF THE DRAWINGS

FIG. 1 shows a field-effect transistor according to the present invention,

FIG. 2 shows another field-effect transistor according to the present invention,

FIG. 3 shows another field-effect transistor according to the present invention,

FIG. 4 shows another field-effect transistor according to the present invention.

### DETAILED DESCRIPTION OF THE INVENTION

Before the invention is described in detail, it is to be understood that this invention is not limited to the particular component parts of the devices described or process steps of the methods described as such devices and methods may vary. It is also to be understood that the terminology used herein is for purposes of describing particular embodiments only, and is not intended to be limiting. It must be noted that, as used in the specification and the appended claims, the singular forms “a,” “an” and “the” include singular and/or plural referents unless the context clearly dictates otherwise. Thus, for example, reference to “an analyte” may include mixtures, reference to “a sensor” includes two or more such devices, and the like.

The gate electrode layer can comprise metals such as Ta, Fe, W, Ti, Co, Au, Ag, Cu, Al and/or Ni or organic materials such as PSS/PEDOT or polyaniline. The primary consideration for choosing the gate electrode material is that it is a good conductor.

The first dielectric layer can comprise amorphous metal oxides such as Al₂O₃, Ta₂O₅, transition metal oxides such as HfO₂, ZrO₂, TiO₂, BaTiO₃, BaₓSr₁₋ₓTiO₃, Pb(ZrₓTi₁₋ₓ)O₃, SrTiO₃, BaZrO₃, PbTiO₃, LiTaO₃, rare earth oxides such as Pr₂O₃, Gd₂O₃, Y₂O₃ or silicon compounds such as Si₃N₄, SiO₂ or microporous layers of SiO and SiOC. Furthermore, the first dielectric layer can comprise polymers such as SU-8 or BCB, PTFE or even air.

The source electrode and the drain electrode can be fabricated using metals such as aluminium, gold, silver or copper or, alternatively, conducting organic or inorganic materials.

The organic semiconductor can comprise materials selected from poly(acetylene)s, poly(pyrrole)s, poly(aniline)s, poly(arylamine)s, poly(fluorene)s, poly(naphthalene)s, poly(p-phenylene sulfide)s or poly(p-phenylene vinylene)s. The semiconductor also may be n-doped or p-doped to enhance conductivity. Furthermore, the organic semiconductor can exhibit a field effect mobility μ of ≧10⁻⁵ cm² V⁻¹ s⁻¹ to ≦10² cm² V⁻¹ s⁻¹, of ≧10⁻⁴ cm²V⁻¹ s⁻¹ to ≦10⁻¹ cm² V⁻¹ s⁻¹ or of ≧10⁻³ cm² V⁻¹ s⁻¹ to ≦10⁻² cm² V⁻¹ s⁻¹.

The second dielectric layer can comprise the same materials as discussed for the first dielectric layer. As the second dielectric layer also shields the layers below from outside conditions, waterproof coatings such as PTFE or silicones may also be taken into consideration.

Characteristic of the present invention is that during operation of the field-effect transistor the capacitance of the assembly comprising the gate electrode layer and the first dielectric layer is lower than the capacitance of the second dielectric layer. It has been found that the sensitivity of the field-effect transistor can be advantageously influenced by this capacitance relation.

During operation of the transistor according to the present invention an analyte can attach to the exterior surface of the second dielectric. By this the local dipole moment and thus the local dielectric constant can change. In combination with the voltage applied to the gate electrode the electrical field experienced by the semiconductor changes which in turn leads to a change in the current between source and drain electrode. This signal can be processed to give information about the presence and concentration of the analyte. The transistor according to the present invention can be described as a dual gated field-effect transistor, the second gate being a ‘floating gate’ electrode made of the analyte bonding to the exterior surface of the second dielectric.

The principle of the ‘floating gate’ electrode allows for the detection of analytes in the gas phase, in the liquid phase and even in the solid phase.

The process of manufacturing a transistor according to the present invention may comprise applying the organic semiconductor by spin coating, drop casting, evaporating and/or printing. These means of applying the organic semiconductor, either in solution or in pure substance, allow for the cheap production of said field-effect transistors. Furthermore, amorphous or highly ordered films with great control of film thickness can be obtained. The mentioned processes not only allow for the coating of regular plain surfaces but also of irregularly shaped surfaces with protrusions and depressions.

It is within the scope of the present invention that the individual components constituting the field-effect transistor according to the present invention are arranged in such a way that the first dielectric layer is placed onto the gate electrode layer, the source electrode, the drain electrode and the organic semiconductor are placed upon the first dielectric layer and the source electrode and the drain electrode are separated by the organic semiconductor, and that the second dielectric layer is placed upon the assembly of source electrode, drain electrode and organic semiconductor.

Furthermore, it is also within the scope of the present invention that the individual components constituting the field-effect transistor according to the present invention are arranged in such a way that the first dielectric layer is placed onto the gate electrode layer, the organic semiconductor is placed upon the first dielectric layer, the source electrode, the drain electrode and the second dielectric are placed upon the organic semiconductor and the source electrode and the drain electrode are separated and covered by the second dielectric.

In one embodiment of the present invention the ratio of the capacitance of the assembly comprising the gate electrode layer and the first dielectric layer to the capacitance of the second dielectric layer is from ≧1:1.1 to ≦1:1000, preferred ≧1:2 to ≦1:500, more preferred ≧1:5 to ≦1:100. With capacitance ratios in these regions the threshold voltages of field-effect transistors according to the present invention can be adapted to operate with desired sensitivity and fast response times needed for continuous on-line analytics.

In another embodiment of the present invention the relative dielectric constant K of the material of the first dielectric layer has a value of ≧1 to ≦100, preferred ≧1.5 to ≦50, more preferred ≧2 to ≦30. These materials allow the thickness of the dielectric to be fine-tuned to the specifically needed design without unduly increasing the capacitance of the assembly or risking leakage currents due to tunneling.

In another embodiment of the present invention the relative dielectric constant K of the material of the second dielectric layer has a value of ≧1.1 to ≦100, preferred ≧1.5 to ≦50, more preferred ≧2 to ≦30. These so-called “high K” dielectrics allow the thickness of the dielectric to be fine-tuned to the specifically needed design without unduly increasing the capacitance of the assembly or risking leakage currents due to tunneling.

In another embodiment of the present invention the thickness of the first dielectric layer has a value of ≧500 nm to ≦2000 nm, preferred ≧700 nm to ≦1500 nm, more preferred ≧900 nm to ≦1100 nm. The sizing of the first dielectric layer is important because thinner layers will lead to leakage currents and thicker layers bear the danger of lower sensitivity in the transistor because the field effect cannot fully influence the semiconducting layer. It is possible that the first dielectric layer is a combination of different materials.

In another embodiment of the present invention the thickness of the second dielectric layer has a value of ≧50 nm to ≦1000 nm, preferred ≧80 nm to ≦170 nm, more preferred ≧100 nm to ≦130 nm. The sizing of the second dielectric layer is important because thinner layers will lead to leakage currents and thicker layers bear the danger of lower sensitivity in the transistor because the field effect cannot fully influence the semiconducting layer. Furthermore, the second dielectric layer protects the organic semiconductor from exposure to the exterior. Therefore, a minimum thickness is required to perform this duty, even during mechanical stress. Especially beneficial for practical operation is if the second dielectric layer is not soluble in water or other solvents it is likely to encounter during operation. It is also possible that the second dielectric layer is a combination of different materials.

In another embodiment of the present invention the thickness of the semiconducting layer, as measured in the channel between source and drain, has a value of ≧2 nm to ≦500 nm, preferred ≧10 nm to ≦200 nm, more preferred ≧30 nm to ≦100 nm. This is to ensure a good signal to noise ratio during operation of the transistor. Thinner layers would show a limited range of operation before the transistor overamplifies and thicker layers would cause the sensitivity of the transistor to decrease.

In another embodiment of the present invention the organic semiconductor is selected from the group comprising pentacene, anthracene, rubrene, phthalocyanine, α,ω-hexathiophene, α,ω-dihexylquaterthiophene, α,ω-dihexylquinquethiophene, α,ω-dihexylhexathiophene, bis(dithienothiophene), dihexyl-anthradithiophene, n-decapentafluorophenylmethylnaphthalene-1,4,5,8-tetracarboxylic diimide, C₆₀, F8BT, poly(p-phenylene vinylene), poly(acetylene), poly(thiophene), poly(3-alkylthiophene), poly(3-hexylthiophene), poly(triarylamines), oligoarylamines and/or poly(thienylenevinylene). The aforementioned materials are well-tested and readily commercially available.

In another embodiment of the present invention the external outer surface of the second dielectric layer further comprises receptor molecules capable of bonding to an analyte, preferably selected from the group comprising anion receptors, cation receptors, arene receptors, carbohydrate receptors, lipid receptors, steroid receptors, peptide receptors, nucleotide receptors, RNA receptors and/or DNA receptors. The receptor molecules may be bond to the surface of the second dielectric layer by covalent, ionic or non-covalent bonds such as Van-der-Waals interactions. It is possible and preferred that the receptor molecules form a self-assembled monolayer (SAM) to ensure closest packing and therefore the maximum number of receptor molecules with respect to the surface area of the second dielectric layer.

The analytes which are bond by the aforementioned receptor molecules represent interesting targets for medical applications. Knowledge of the presence or concentration of these analytes gives valuable insight into the formation or occurrence of diseases. Anions and cations are not limited to simple species like alkaline, alkaline earth, halogenide, sulphate and phosphate but also extend to species like amino acids or carboxylic acids which are formed during metabolic processes in cells. Arene receptors may be employed if the presence of, for example, carcinogenic arenes like polycyclic aromatic hydrocarbons (PAH) is suspected. Carbohydrate receptors may be used in areas like the treatment of diabetes. Lipid receptors may find application if metabolic diseases in connection with adipositas are to be investigated. Steroid receptors which are sensitive to steroid hormones are useful for a wide range of indication areas including pregnancy tests and doping control in commercial sports. The detection of peptides, nucleotides, RNA and DNA is important for the research and treatment of hereditary diseases and cancer.

When an analyte bonds to a receptor molecule a change in the dipole moment of the receptor molecule can be observed. This in turn leads to a change in the electric field controlling the current between source and drain electrode. Therefore, a signal can be observed and correlated with an analyte. Whereas this behaviour is most easily associated with charged analytes, the detection of non-charged analytes in a surrounding polar medium such as the water of physiological solutions is also possible. When a neutral analyte bonds to the receptor molecule, water molecules are displaced from the receptor molecules or the surface. This results in a change in the dielectric constant of the receptor molecule or the dielectric.

With the present invention it is possible to devise a method for detecting analytes comprising a field-effect transistor according to the present invention. In this, during operation of the field-effect transistor, the capacitance of the assembly gate electrode layer-first dielectric layer is lower than the capacitance of the second dielectric layer. The advantages of this operational characteristic have already been discussed above.

Another aspect of the present invention is a sensor system comprising at least one field-effect transistor according to the present invention. The sensor system can comprise a housing for one or more of the field-effect transistors and electrical circuitry for signal processing. The individual field-effect transistors may be sensitive to the same analyte or to different analytes. Owing to the possibility of cheaply manufacturing a field-effect transistor according to the present invention a disposable sensor system can be conceived. This is important when dealing with infectious material such as blood or other bodily fluids.

A further aspect of the present invention is the use of a sensor system according to the present invention for detecting molecules. The molecules to be detected may be selected from the group comprising anions, cations, arenes, carbohydrates, steroids, lipids, nucleotides, RNA and/or DNA. The molecules from this group serve as valuable indicators for cellular processes and are targets for analytical devices.

Areas in which the sensor system may be used can be chemical, diagnostic, medical and/or biological analysis, comprising assays of biological fluids such as egg yolk, blood, serum and/or plasma; environmental analysis, comprising analysis of water, dissolved soil extracts and dissolved plant extracts as well as quality safeguarding analysis.

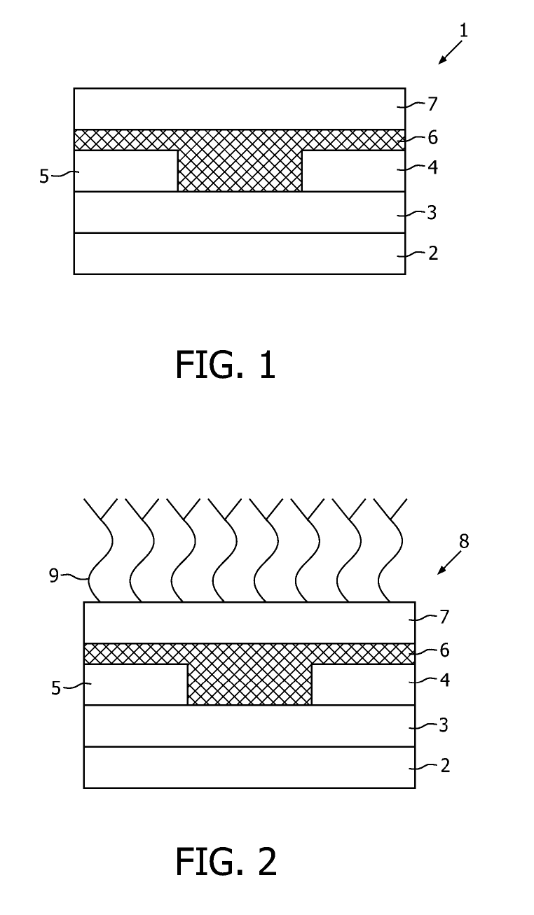

FIG. 1 shows a first field-effect transistor according to the present invention (1) comprising a gate electrode layer (2). On top of this layer is a first dielectric layer (3). The first dielectric layer (3) is in contact with a source electrode (4), a drain electrode (5) and an organic semiconductor (6). It can be seen that the organic semiconductor (6) fills the gap between source electrode (4) and drain electrode (5) and additionally covers the top of electrodes (4) and (5). The upper surface of semiconductor (6) is in contact with the second dielectric (7).

FIG. 2 shows a second field-effect transistor according to the present invention (8). This transistor corresponds to the transistor already depicted in FIG. 1 with the additional feature of a layer of receptor molecules (9) bond to the surface of second dielectric (7).

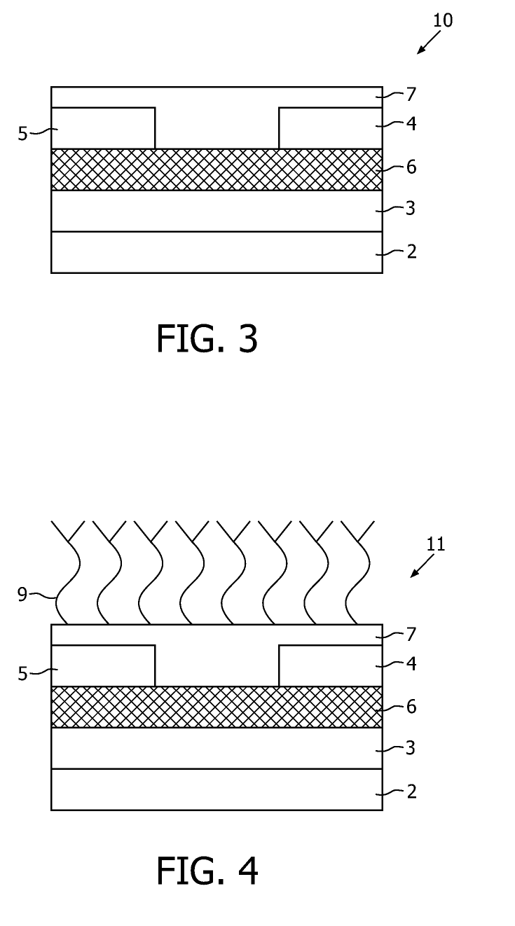

FIG. 3 shows a third field-effect transistor according to the present invention (10) comprising a gate electrode layer (2). On top of this layer is a first dielectric layer (3). Above this, the organic semiconductor (6) is arranged. On top of organic semiconductor (6), source electrode (4) and drain electrode (5) are placed. The second dielectric layer (7) covers and separates the source electrode (4) and the drain electrode (5).

FIG. 4 shows a fourth field-effect transistor according to the present invention (11). This transistor corresponds to the transistor already depicted in FIG. 3 with the additional feature of a layer of receptor molecules (9) bond to the surface of second dielectric (7).

To provide a comprehensive disclosure without unduly lengthening the specification, the applicant hereby incorporates by reference each of the patents and patent applications referenced above.

The particular combinations of elements and features in the above detailed embodiments are exemplary only; the interchanging and substitution of these teachings with other teachings in this and the patents/applications incorporated by reference are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. The invention's scope is defined in the following claims and the equivalents thereto. Furthermore, reference signs used in the description and claims do not limit the scope of the invention as claimed.

1. Field-effect transistor (1) comprising
a gate electrode layer (2),
a first dielectric layer (3),
a source electrode (4),
a drain electrode (5),
an organic semiconductor (6) and
a second dielectric layer (7),
wherein
the first dielectric layer (3) is located on the gate electrode layer (2),
the source electrode (4), the drain electrode (5) and the organic semiconductor (6) are located above the first dielectric layer (3),
the source electrode (4) and the drain electrode (5) are in contact with the organic semiconductor (6) and
wherein the second dielectric layer (7) is placed upon the assembly of source electrode (4), drain electrode (5) and organic semiconductor (6),
characterized in that during operation of the field-effect transistor (1) the capacitance of the assembly comprising the gate electrode layer (2) and the first dielectric layer (3) is lower than the capacitance of the second dielectric layer (7).

2. Field-effect transistor (1) according to claim 1, wherein the ratio of the capacitance of the assembly comprising the gate electrode layer (2) and the first dielectric layer (3) to the capacitance of the second dielectric layer (7) is from ≧1:1.1 to ≦1:1000.

3. Field-effect transistor (1) according to claim 1, wherein the relative dielectric constant K of the material of the second dielectric layer (7) has a value of ≧1.1 to ≦100.

4. Field-effect transistor (1) according to claim 1, wherein the thickness of the first dielectric layer (3) has a value of ≧500 nm to ≦2000 nm.

5. Field-effect transistor (1) according to claim 1, wherein the thickness of the second dielectric layer (7) has a value of ≧50 nm to ≦1000 nm.

6. Field-effect transistor (1) according to claim 1, wherein the thickness of the semiconducting layer (6), as measured in the channel between source (4) and drain (5), has a value of ≧2 nm to ≦500 nm.

7. Field-effect transistor (1) according to claim 1, wherein the organic semiconductor (6) is selected from the group comprising pentacene, anthracene, rubrene, phthalocyanine, α,ω-hexathiophene, α,ω-dihexylquaterthiophene, α,ω-dihexylquinquethiophene, α,ω-dihexylhexathiophene, bis(dithienothiophene), dihexylanthradithiophene, n-decapentafluorophenylmethylnaphthalene-1,4,5,8-tetracarboxylic diimide, C₆₀, F8BT, poly(p-phenylene vinylene), poly(acetylene), poly(thiophene), poly(3-alkylthiophene), poly(3-hexylthiophene), poly(triarylamines), oligoarylamines and/or poly(thienylenevinylene).

8. Field-effect transistor (8) according to claim 1, wherein the external outer surface of the second dielectric (7) layer further comprises receptor molecules (9) capable of bonding to an analyte, preferably selected from the group comprising anion receptors, cation receptors, arene receptors, carbohydrate receptors, lipid receptors, steroid receptors, peptide receptors, nucleotide receptors, RNA receptors and/or DNA receptors.

9. Sensor system comprising at least one field-effect transistor according to claim 1.

10. Use of a sensor system according to claim 9 for detecting molecules.
